(19) United States
(12) Patent Application Publication
(10) Pub. No.: US 2025/0266364 A1
(43) Pub. Date: Aug. 21, 2025

(54) METHOD FOR MANUFACTURING CARRIER PLATE, POWER SUPPLY MODULE, ASSEMBLY METHOD THEREFOR AND MAGNETIC ASSEMBLY

(71) Applicant: SHANGHAI METAPWR ELECTRONICS CO., LTD, Shanghai (CN)

(72) Inventors: Qingdong CHEN, Shanghai (CN); Shouyu HONG, Shanghai (CN); Yahong Xiong, Shanghai (CN)

(73) Assignee: SHANGHAI METAPWR ELECTRONICS CO., LTD, Shanghai (CN)

(21) Appl. No.: 19/057,987

(22) Filed: Feb. 20, 2025

(30) Foreign Application Priority Data
Feb. 20, 2024 (CN) 202410189718.3

(51) Int. Cl. H01L 23/538; H01L 21/48; H01L 23/498; H01L 25/18; H10D 1/68

(52) U.S. Cl. CPC H01L 23/5383; H01L 21/4853; H01L 21/486; H01L 23/49816; H01L 23/5386; H01L 25/18; H10D 1/68

(57) ABSTRACT

The application provides a manufacturing method of a carrier plate, a power supply module and an assembling method of the power supply module. The manufacturing method of the carrier plate includes the following steps: step 1, forming a substrate; step 2, vertically drilling a hole, and forming a connector; step 3, performing mechanical drilling to form a hole; and step 4, performing depth-controlled milling groove, wherein the power supply module includes a carrier plate, a magnetic core, a first assembly and a third assembly; the magnetic core includes a magnetic column, a first magnetic cover plate and a second magnetic cover plate, the magnetic column penetrates through the hole, and the first magnetic cover plate and the second magnetic cover plate are respectively accommodated in the first depth-controlled groove and the second depth-controlled groove and are buckled with the magnetic column to form a second assembly.

### CROSS-REFERENCE TO RELATED APPLICATIONS

This application claims the priority benefit of Chinese patent application CN202410189718.3, filed on Feb. 20, 2024. The entirety of the above-mentioned patent application is hereby incorporated by reference herein and made a part of this specification.

### BACKGROUND

### Technical Field

The invention belongs to the technical field of high frequency power supply, and in particular relates to a method for manufacturing a carrier plate, a power supply module and an assembly method thereof.

### Description of Related Art

In recent years, with the development of technologies such as data centers, artificial intelligence, supercomputers and the like, more and more ASIC with powerful functions are applied, such as a CPU, a GPU, a machine learning accelerator chip, a network switch chip and the like; a large amount of current is consumed, for example, the required current can reach thousands of amperes; and the consumed current has the characteristic of rapid jump. A power supply module comprising buck circuits (Buck) is traditionally used to supply such loads; these power supply modules tend to move from a solution coplanar with the ASIC and supplying power to the ASIC, and move to a solution that is out-of-plane with the ASIC and vertically supplies power to the ASIC. At present, for the power supply module vertically supplies power to the ASIC, how to improve the efficiency of the power supply module, how to reduce the size of the power supply module, and how to improve the integration level and the application reliability of the power supply module are the key problems needing to be urgently solved.

### SUMMARY

In view of the above, one of the objectives of the application is to provide a manufacturing method of a carrier plate includes the following steps:
Step 1, preparing thick copper, a first double-sided copper-clad plate, a second double-sided copper-clad plate, a first PP layer and a second PP layer, wherein the first double-sided copper-clad plate is arranged on the top surface of the thick copper through a first PP layer, the second double-sided copper-clad plate is arranged on the bottom surface of the thick copper through a second PP layer, and the double-sided copper-clad plate, the PP layer and the thick copper are cured at high temperature to form a substrate; the substrate includes a connecting area and a winding area;
Step 2, a hole is vertically drilled in the connecting area, and after the inner wall of the hole is electroplated and the hole is filled with the resin, the top surface and the bottom surface of the hole are subjected to surface electroplating to form a connector; the connector is electrically connected with the thick copper;
Step 3, performing mechanical drilling on the winding area to form a hole penetrating through the substrate;
Step 4, performing depth-controlled milling on the top surface and the bottom surface of the winding area to form a first depth-controlled groove and a second depth-controlled groove.

Preferably, wherein the sum of the thicknesses of the first double-sided copper-clad plate and the first PP layer is equal to the sum of the thicknesses of the second double-sided copper-clad plate and the second PP layer; and the height of the first depth-controlled groove is equal to the height of the second depth-controlled groove.

Preferably, wherein the connector is electrically connected with a wiring layer in the substrate, and the connector includes a top surface bonding pad arranged on the top surface of the substrate and a bottom surface bonding pad arranged on the bottom surface of the substrate.

Preferably, wherein part of PP layers are reserved at the bottoms of the first depth-controlled groove and the second depth-controlled groove, and the PP layer is removed through a laser etching process.

Preferably, wherein an insulating layer is formed on the exposed surface of the thick copper in a spraying mode to form a carrier plate.

A power supply module includes a first assembly, a second assembly and a third assembly; and the first assembly, the second assembly and the third assembly are sequentially stacked; and the second assembly includes a carrier plate and a magnetic core; and the carrier plate includes a top surface and a bottom surface which are opposite to each other, a hole, a connector, a first depth-controlled groove, a second depth-controlled groove, a winding area and a connecting area; the first depth-controlled groove is concaved from the top surface of the carrier plate, and the second depth-controlled groove is concaved from the bottom surface of the carrier plate; the winding area is a part of the second carrier plate between the first depth-controlled groove and the second depth-controlled groove; the hole is formed in the winding area, and the hole penetrates through the top surface and the bottom surface of the carrier plate; the connector is provided with a connecting area; the power supply module further includes a winding, and the winding is arranged in a winding area of the carrier plate; the magnetic core includes a magnetic column, a first magnetic cover plate and a second magnetic cover plate, the magnetic column penetrates through the hole, the first magnetic cover plate and the second magnetic cover plate are accommodated in the first depth-controlled groove and the second depth-controlled groove respectively, and the first magnetic cover plate and the second magnetic cover plate are buckled with the magnetic column;

The first assembly and the third assembly are arranged on the top surface and the bottom surface of the second assembly respectively, and the first assembly and the third assembly are electrically connected through the connector.

Preferably, wherein the thickness of the first magnetic cover plate is smaller than or equal to the height of the first depth-controlled groove, and the thickness of the second magnetic cover plate is smaller than or equal to the height of the second depth-controlled groove.

Preferably, wherein the carrier plate is a second carrier plate; the first assembly includes a first carrier plate, a switch device and an input capacitor; the first carrier plate includes a top surface and a bottom surface which are opposite; the bottom surface of the first carrier plate is arranged adjacent to the top surface of the second carrier plate; the switch device is arranged on the top surface of the first carrier plate; and the input capacitor is arranged on the bottom surface of the first carrier plate.

Preferably, the input capacitor is accommodated in the first depth-controlled groove, and the sum of the thickness of the input capacitor and the thickness of the first magnetic cover plate is smaller than or equal to the height of the first depth-controlled groove.

Preferably, wherein the third assembly includes a third carrier plate, an output capacitor and a welding ball; the third carrier plate includes a top surface and a bottom surface opposite to each other, and the top surface of the third carrier plate is arranged adjacent to the bottom surface of the second carrier plate; and the output capacitor is arranged on the top surface of the third carrier plate, and the solder ball is arranged on the bottom surface of the third carrier plate.

Preferably, wherein the output capacitor is accommodated in the second depth-controlled groove, and the sum of the thickness of the output capacitor and the thickness of the second magnetic cover plate is smaller than or equal to the height of the second depth-controlled groove.

Preferably, wherein the connector includes a via hole, a top surface bonding pad and a bottom surface bonding pad; and the via hole is electrically connected with the top surface bonding pad and the bottom surface bonding pad.

Preferably, wherein the connector includes side wall electroplating, a top surface bonding pad and a bottom surface bonding pad, and the side wall electroplating is electrically connected to the top surface bonding pad and the bottom surface bonding pad.

Preferably, wherein the connector includes a power electrical connector and a signal electrical connector; and the carrier plate further includes a thick copper layer and a copper-clad layer, and the signal electrical connector is electrically connected with the thick copper layer and the copper-clad layer.

Preferably, the connection area surrounds the winding area.

Preferably, wherein the winding can be an internal wiring of the carrier plate or a copper sheet embedded in the carrier plate.

Preferably, the power supply module further includes a bonding layer and an insulation layer, the bonding layer and/or the insulation layer can cover part or whole of the winding and the bonding layer is disposed between the magnetic core and the insulation layer.

A method for assembling a power supply module includes the following steps:
Step 1, buckling the magnetic core and the second carrier plate to form a second assembly;
Step 2, welding an output capacitor and the second assembly formed in the step 1 on the top surface of the third carrier plate to form a first assembly;
Step 3, ball-implanting a ball on the bottom surface of the third carrier plate to form a second combination body;
Step 4, welding a switch device on the top surface of the first carrier plate;
Step 5, welding an input capacitor and the second combination body formed in the step 3 on the bottom surface of the first carrier plate to form the power supply module.

The step 4 can be completed in any step before the step 5.

A method for assembling a power supply module includes the following steps:
Step 1, buckling the magnetic core and the second carrier plate to form a second assembly;
Step 2, ball-implanting a solder ball on the bottom surface of the third carrier plate;
Step 3, welding an output capacitor and the second assembly formed in the step 1 on the top surface of the third carrier plate to form a first combination body;
Step 4, welding a switch device on the top surface of the first carrier plate;
Step 5, welding an input capacitor and the first combination body formed in the step 3 on the bottom surface of the first carrier plate to form the power supply module.

The step 2 can be completed in any step before the step 3, and the step 4 can be completed in any step before the step 5.

A method for assembling the power supply module includes the following steps:
Step 1, buckling the magnetic core and the second carrier plate to form a second assembly;
Step 2, ball-implanting a solder ball on the bottom surface of the third carrier plate;
Step 3, welding an input capacitor and the second assembly formed in the step 1 on the bottom surface of the third carrier plate to form a first combination body;
Step 4, welding a switch device on the top surface of the first carrier plate;
Step 5, welding an output capacitor and the first combination body formed in the step 3 on the top surface of the third carrier plate to form the power supply module.

The step 2 can be completed in any step before the step 3, and the step 4 can be completed in any step before the step 5.

A method for assembling a power supply module includes the following steps:
Step 1, buckling the magnetic core and the second carrier plate to form a second assembly; Step 2, welding an output capacitor and a second assembly formed in the step 1 on the top surface of the third carrier plate to form a first combination body;
Step 3, welding a switch device and a top surface input capacitor on the top surface of the first carrier plate;
Step 4, arranging a bottom surface input capacitor and the first combination body formed in the second step on the bottom surface of the first carrier plate, arranging a welding ball on the bottom surface of the third carrier plate, and carrying out reflow soldering to form a power supply module.

The step 3 can be completed in any step before the step 4.

A magnetic assembly includes a carrier plate, a magnetic core and a winding; the winding can be an internal wiring of the carrier plate or a metal sheet embedded in the carrier plate; the magnetic core includes a magnetic column, a first magnetic cover plate and a second magnetic cover plate, the magnetic column is disposed between the first magnetic cover plate and the second magnetic cover plate; the carrier plate includes a top surface and a bottom surface which are opposite to each other, and the hole penetrates through the top surface and the bottom surface of the carrier plate; the magnetic column penetrates through the hole, and the first magnetic cover plate and the second magnetic cover plate are buckled the carrier plate with the magnetic column;

the magnetic assembly further includes a bonding layer and an insulation layer, the bonding layer and/or the insulation layer can cover part or all of the windings and the bonding layer is disposed between the magnetic core and the insulation layer.

Preferably, the carrier plate includes a first depth-controlled groove, a second depth-controlled groove, a winding area and a connecting area; the first depth-controlled groove is concaved from the top surface of the carrier plate, and the second depth-controlled groove is concaved from the bottom surface of the carrier plate; the winding area is part of a carrier plate between a first depth-controlled groove and a second depth-controlled groove; the hole is arranged in the winding area; the first magnetic cover plate and the second magnetic cover plate are accommodated in the first depth-controlled groove and the second depth-controlled groove respectively.

Preferably, wherein the connection area surrounds the winding area; the magnetic assembly further includes a connector, wherein the connector includes a via hole, a top surface bonding pad and a bottom surface bonding pad; and the via hole is electrically connected with the top surface bonding pad and the bottom surface bonding pad.

Preferably, wherein the connector includes a power electrical connector and a signal electrical connector; and the carrier plate further includes a thick copper layer and a copper-clad layer, and the signal electrical connector is electrically connected with the thick copper layer and the copper-clad layer.

Compared with the prior art, the application has the following beneficial effects:
(1) the structure of the power supply module is provided, and the number of times of reflow soldering of components in the power supply module is reduced;
(2) According to the manufacturing process of the power supply module, the assembly error of the module can be effectively reduced, the space utilization rate of the magnetic assembly in the power supply module is improved, and the size of the power supply module is reduced.
(3) A magnetic assembly is proposed, the magnetic assembly includes an insulation layer and a bonding layer on at least part of the surface of the winding, which can further enhance the bonding strength between the magnetic core and the winding.

### BRIEF DESCRIPTION OF THE DRAWINGS

FIG. 1 is a schematic side view of a power supply module according to Embodiment 1;

FIG. 2A is a schematic side view of a power supply module according to Embodiment 2;

FIG. 2B is a three-dimensional decomposition schematic diagram of a power supply module according to Embodiment 2;

FIG. 2C is a schematic side view of a second assembly 2 according to Embodiment 2;

FIG. 2D is a three-dimensional top view of the second assembly 2 according to Embodiment 2;

FIG. 3A to FIG. 3E are a production process flow of the second assembly 2 shown in FIG. 2D.

### DESCRIPTION OF THE EMBODIMENTS

One of the cores of the present application is to provide a power supply module structure and a manufacturing process.

The technical solutions in the embodiments of the present application will be clearly and completely described below with reference to the accompanying drawings in the embodiments of the present application, and obviously, the described embodiments are only a part but not all of the embodiments of the present application. All other embodiments obtained by a person of ordinary skill in the art based on the embodiments of the present application without creative efforts shall fall within the protection scope of the present application.

### Embodiment 1

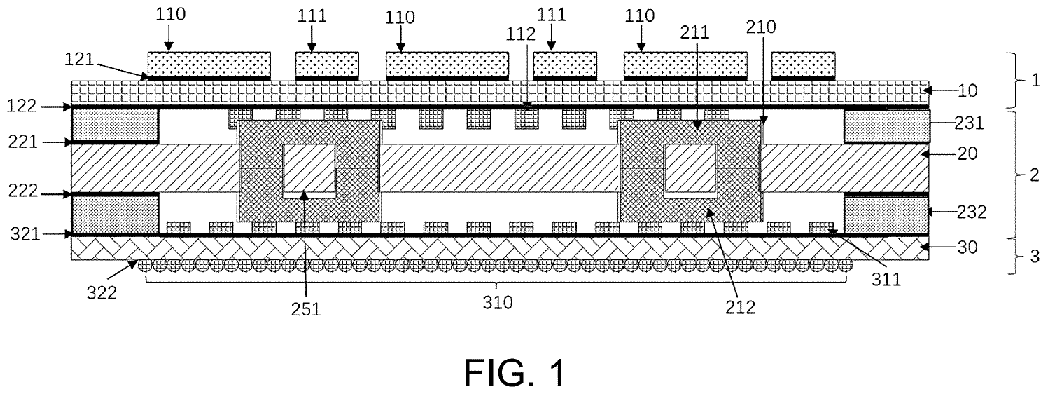

FIG. 1 is a schematic side view of the power supply module according to the embodiment, the power supply module comprises a first assembly 1, a second assembly 2 and a third assembly 3. The first assembly 1 comprises a first carrier plate 10, an active element 110 such as a switch element and a passive element such as a top surface input capacitor 111 and a bottom surface input capacitor 112. The switch element 110 and the top surface input capacitor 111 are welded to the top surface of the first carrier plate 10 through the first welding layer 121; and the bottom surface input capacitor 112 is welded to the bottom surface of the first carrier plate 10 through the second welding layer 122. The third assembly 3 comprises a third carrier plate 30, a passive element 311 such as an output capacitor, and a solder ball. The output capacitor 311 is welded to the top surface of the third carrier plate 30 through a third welding layer 321; the solder ball 310 is planted on the bottom surface of the third carrier plate 30 as functional pins of the power supply module, and a fourth welding layer 322 is formed. The second assembly 2 comprises a second carrier plate 20, a magnetic assembly and an electrical connector. The magnetic assembly comprises a winding and a magnetic core 210; the winding is arranged in the second carrier plate 20; when the second carrier plate 20 is a multilayer substrate similar to a printed circuit board (PCB), the winding can be formed by wiring in the PCB, and can also be formed by a copper sheet embedded in the PCB. The magnetic column of the magnetic core 210 passes through the second carrier plate 20, and the first magnetic cover plate 211 and the second magnetic cover plate 212 of the magnetic core 210 are respectively buckled with the winding from the top surface and the bottom surface of the second carrier plate 20 to form a magnetic assembly. The bottom surface of the electrical connector 231 is welded to the top surface of the second carrier plate 20 through a fifth welding layer 221, and the top surface of the electrical connector 232 is welded to the bottom surface of the second carrier plate 20 through a sixth welding layer 222. And the top surface of the electrical connector 231 is welded and fixed to the first assembly 1 through a second welding layer 122, so that the first assembly 1 and the second assembly 2 are fixed and electrically connected; and the bottom surface of the electrical connector 232 is welded and fixed to the third assembly 3 through a third welding layer 321, so that the second assembly 2 and the third assembly 3 are fixed and electrically connected.

The power supply module in the embodiment comprises six welding layers, so that in the assembling process of the power supply module, the reflow soldering times experienced by some devices in the power supply module are difficult to be controlled to be less than or equal to three times; therefore, the power supply module is high in production process difficulty and low in production yield, and the application reliability of the power supply module is greatly reduced. Therefore, the urgent problems are reducing the number of welding layers of the power supply module and improving the production yield and the application reliability of the power supply module.

### Embodiment 2

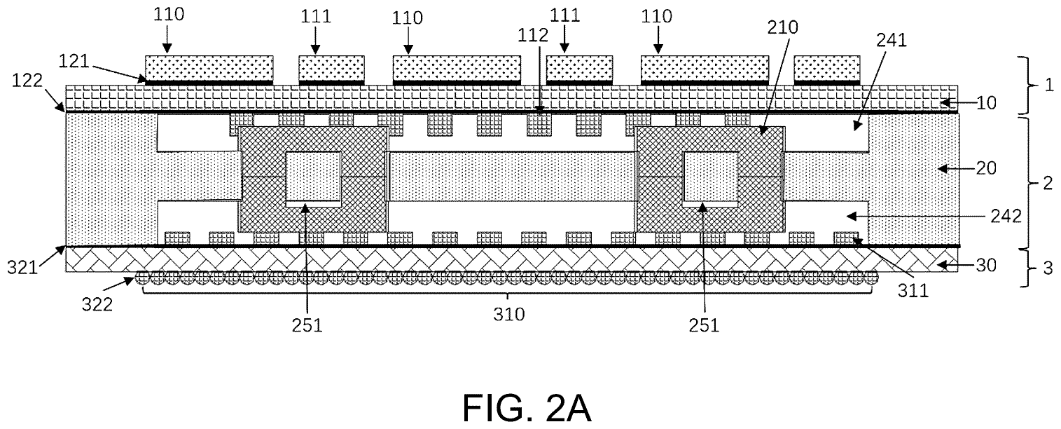

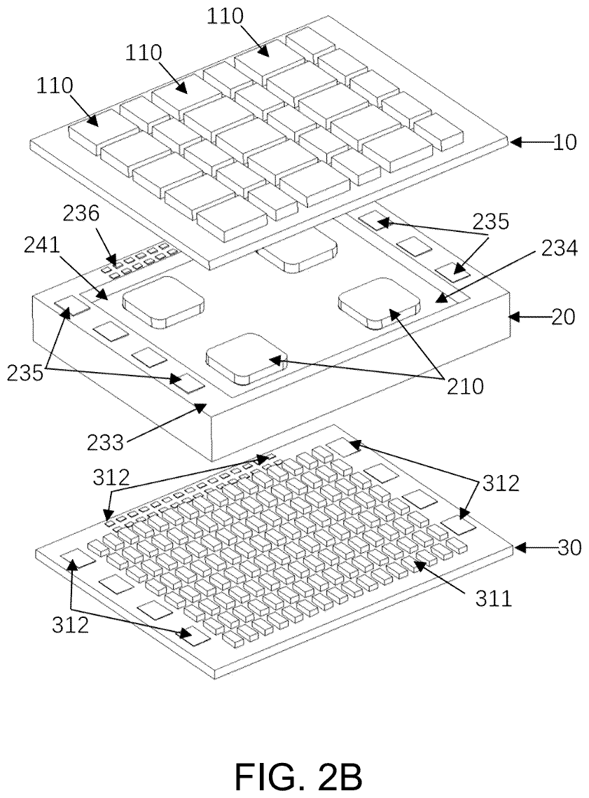

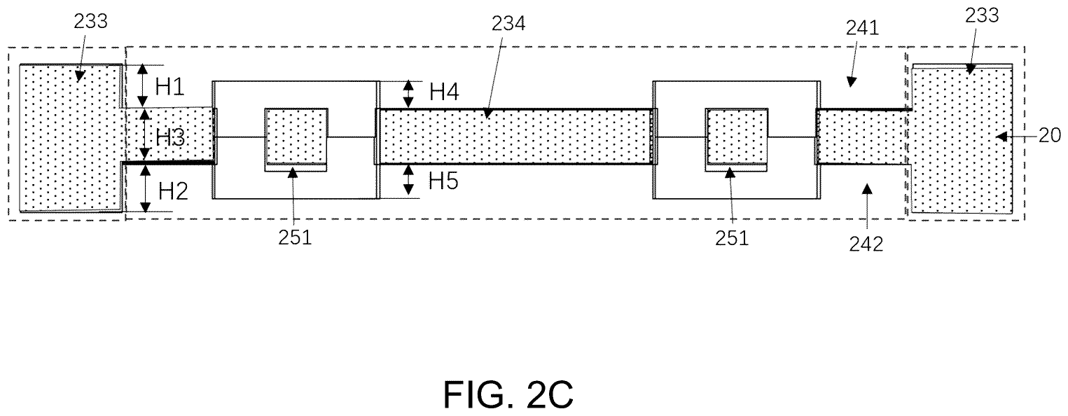

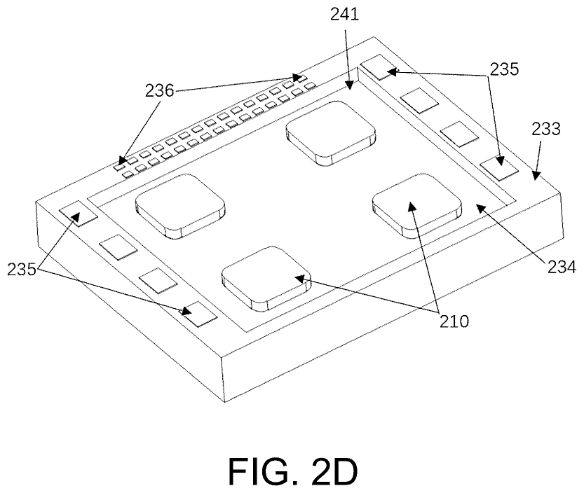

In order to solve the problem shown in the embodiment of FIG. 1, the embodiment provides a power supply module, and FIG. 2A is a side view schematic diagram of the power supply module according to the embodiment; FIG. 2B is a three-dimensional decomposition schematic diagram of the power supply module in the embodiment; FIG. 2C is a side view schematic diagram of the second assembly 2 in the power supply module according to the embodiment; and FIG. 2D is a three-dimensional top view diagram of the second assembly 2 in the power supply module in the embodiment. In the embodiment, the structures of the first assembly 1 and the third assembly 3 are the same as those in the first embodiment; and the difference lies in the absence of electrical connectors 231 and 232, which are similar to copper blocks, in the second assembly 2. But the second carrier plate 20 in the second assembly 2 comprises a special-shaped structure of the first depth-controlled groove 241 and the second depth-controlled groove 242, so that the second assembly 2 does not comprise the fifth welding layer and the sixth welding layer; so that the six welding layers in the first embodiment are reduced into four welding layers, and the reflow soldering times of the devices in the embodiment in the power supply module assembling process can be reduced to be within three or three times. The assembly process flow of the power supply module in the embodiment is as follows:
Step 1, respectively buckling and bonding the magnetic cores 210 from two opposite side of the second carrier plate 20 to form a second assembly 2;
Step 2, placing an output capacitor 311 and a second assembly 2 formed in the step 1 on the top surface of the third carrier plate 30, and carrying out reflow soldering to form a first assembly, wherein, the magnetic assembly and the output capacitor 311 undergo first reflow soldering.
Step 3, placing a welding ball 310 on the bottom surface of the third carrier plate 30, and carrying out reflow soldering to form a second combination body, wherein, the welding ball 310 undergoes first reflow soldering, and the magnetic assembly and the output capacitor 311 undergo second reflow soldering.
Step 4, placing a switch element 110 and a top surface input capacitor 111 on the top surface of the first carrier plate 10, and carrying out reflow soldering, and at the moment, the switch element 110 and the top surface input capacitor 111 undergo first reflow soldering.
Step 5, placing a bottom surface input capacitor 112 and the second combination body formed in the step 3 on the bottom surface of the first carrier plate 10, and carrying out reflow soldering, wherein, the bottom surface input capacitor 112 undergoes first reflow soldering; the solder ball 310, the switch element 110 and the top surface input capacitor 111 undergo second reflow soldering; the output capacitor 311 and the magnetic component respectively undergo third reflow soldering, and finally a power supply module is formed; in the assembly process flow, step 4 can be completed in any step before step 5.

Therefore, the solder ball 310, the top surface input capacitor 111 and the switch element 110 are subjected to two reflow soldering processes respectively, and the output capacitor 311 and the magnetic component respectively undergo three reflow soldering processes. By adopting the module structure shown in FIG. 2A and the assembly process flow of the power supply module, the reflow soldering frequency of the welding ball 310 can be controlled twice; due to the fact that the welding ball 310 serves as a pin of the module, the welding reliability of the welding ball 310 is critical; the smaller the reflow soldering times experienced by the welding ball 310 in the assembling process, the smaller the collapse degree of the welding ball 310 is; and the good flatness of the bottom surface of the module can be guaranteed, and the welding reliability of the welding ball 310 is improved.

The assembly process flow I can also be adjusted to be the following assembly process flow II of the power supply module:
Step 1, respectively buckling and bonding the magnetic cores 210 from two opposite side of the second carrier plate 20 to form a second assembly 2;
Step 2, placing a welding ball 310 on the bottom surface of the third carrier plate 30, and carrying out reflow soldering;
Step 3, placing an output capacitor 311 and the second assembly 2 formed in the step 1 on the top surface of the third carrier plate 30, and carrying out reflow soldering to form a first assembly;
Step 4, placing a switch element 110 and a top surface input capacitor 111 on the top surface of the first carrier plate 10, and carrying out reflow soldering;
Step 5, placing a bottom surface input capacitor 112 and the first combination body formed in the step 3 on the bottom surface of the first carrier plate 10, and carrying out reflow soldering again.

In the assembly process flow, step 2 can be completed in any step before step 3, and step 4 can be completed in any step before step 5. The same technical effect can also be obtained by the above assembly process flow.

Furthermore, the step 3 can be combined into the step 5, that is, the bottom surface input capacitor 112 and the first combination body formed in the step 2 are placed on the bottom surface of the first carrier plate 10 at the same time, meanwhile, the welding ball 310 is arranged on the bottom surface of the third carrier plate 30, and reflow soldering is carried out; therefore, the reflow soldering frequency of the solder ball 310 can be reduced from 2 times to 1 time, and the reflow soldering times of the magnetic assembly and the output capacitor 311 are reduced from three times to 2 times. Specifically:
Step 1, respectively buckling and bonding the magnetic cores 210 from two opposite side of the second carrier plate 20 to form a second assembly 2;
Step 2, placing an output capacitor 311 and the second assembly 2 formed in the step 1 on the top surface of the third carrier plate 30 to form a first assembly, and carrying out reflow soldering; wherein, the first reflow soldering is carried out on the magnetic assembly and the output capacitor 311.
Step 3, placing a switch element 110 and a top surface input capacitor 111 on the top surface of the first carrier plate 10 for reflow soldering, and wherein, the switch element 110 and the top surface input capacitor 111 undergo first reflow soldering.
Step 4, placing a bottom surface input capacitor 112 and the first assembly formed in the second step on the bottom surface of the first carrier plate 10, placing a solder ball 310 on the bottom surface of the third carrier plate 30, and carrying out reflow soldering. Wherein, the switch element 110 and the top surface input capacitor 111 undergo second reflow soldering; the solder ball 310 and the bottom surface input capacitor 112 undergo first reflow soldering, and finally, a power supply module is formed.

In addition, in the power supply module structure shown in FIG. 2A, the second carrier plate 20 is of a special-shaped structure, that is, the first depth-controlled groove 241 and the second depth-controlled groove 242 are formed in the top surface and the bottom surface of the second carrier plate 20. With reference to FIG. 2B and FIG. 2C, a part of the second carrier plate between the first depth-controlled groove 241 and the second depth-controlled groove 242 is a winding area 234, and a part of the second carrier plate surrounding the depth-controlled groove is a connecting area 233. As shown in FIG. 2D, the power electrical connector 235 and the signal electrical connector 236 are arranged in the connecting area 233 and respectively comprise a top surface bonding pad arranged on the top surface of the connecting area 233 and a bottom surface bonding pad arranged on the bottom surface of the connecting area 233. The power electrical connector 235 is welded and electrically connected to the first carrier plate 10 by means of the top surface bonding pad, is welded and electrically connected to the third carrier plate 30 by means of the bottom surface bonding pad, and is used to electrical connect the windings in the second carrier plate 20, the first carrier plate 10 and the third carrier plate 30, respectively. The signal electrical connector 236 is welded and electrically connected with the first carrier plate through the top surface bonding pad, is welded and electrically connected with the third carrier plate through the bottom surface bonding pad, and is used for realizing signal electrical connection between the first carrier plate 10 and the third carrier plate 30. In the embodiment, the connecting area 233 surrounds the winding area 234; in other embodiments, the connecting area 233 can also be arranged in the range of the winding area 234, so that the parasitic resistance between the winding area 234 and the connecting area 233 is reduced.

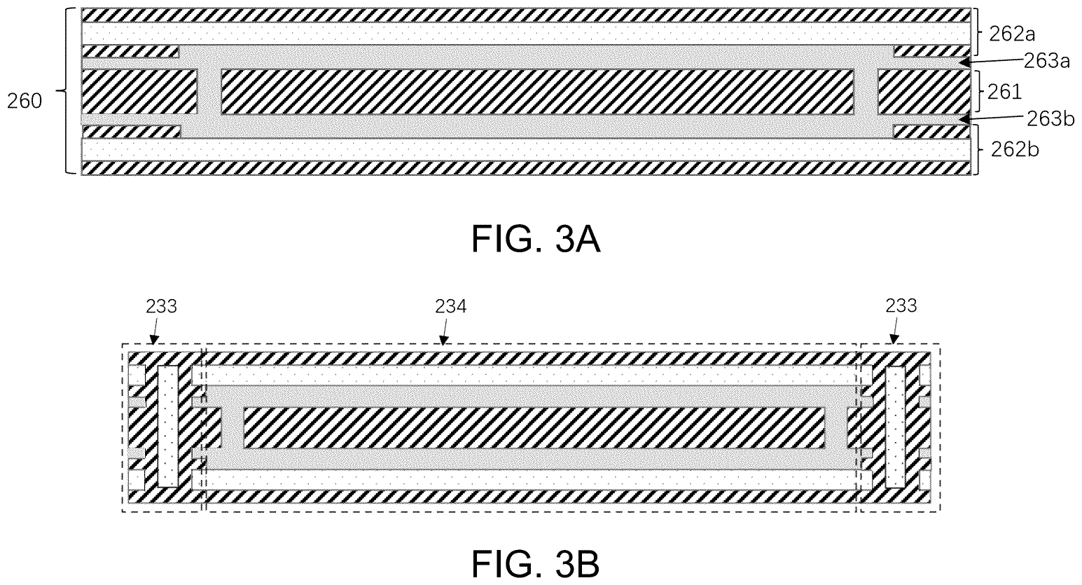

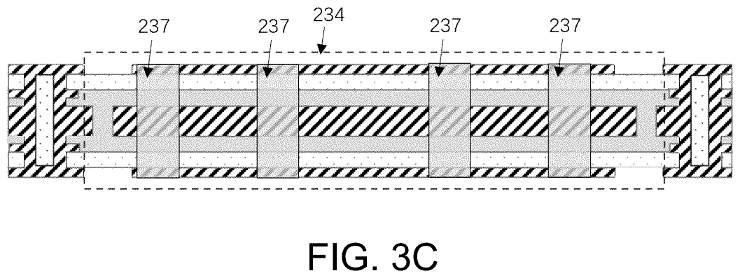

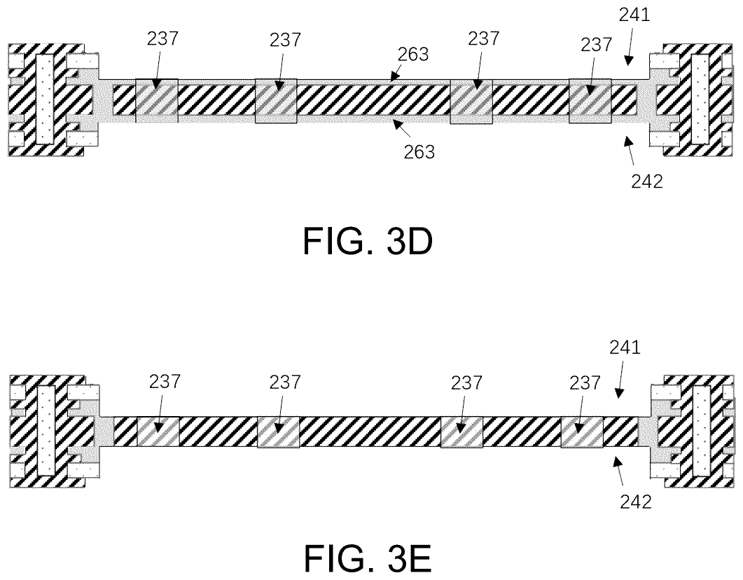

Referring to FIG. 2B, in the embodiment, the third assembly 3 comprises a third carrier plate 30, an output capacitor 311 and a plurality of connector pads 312, wherein the plurality of connector pads 312 are respectively used for being welded and fixed to the bottom surface pads of the power electrical connector 235 and the signal electrical connector 236. The output capacitor 311 is arranged on area of the third carrier plate and the area is vertically corresponding to the winding area 234 of the second carrier plate 20. The plurality of connector pads 312 are arranged around the output capacitor 311, that is, in a region vertically corresponding to the connecting area 233 of the second carrier plate 20. In some other embodiments, the plurality of connector pads 312 may also be disposed among the output capacitors 311, that is, as long as the plurality of connector pads 312 are vertically corresponding to the connection area 233 of the second carrier plate 20. Referring to FIG. 2C, the depths of the first depth-controlled groove 241 and the second depth-controlled groove 242 are H1 and H2 respectively, and the thickness of the winding area 234 of the second carrier plate 20 is H3. When the magnetic core 210 is buckled with the second carrier plate from the top surface and the bottom surface of the winding area 234, the height of the magnetic core protruding out of the top surface of the winding area 234 is H4, that is, the thickness of the first magnetic cover plate 211 is H4; the height of the magnetic core protruding from the bottom surface of the winding area 234 is H5, that is, the sum of the thickness of the second magnetic cover plate 212 and the height of the gap 251 is H5; here, the gap 251 is a gap between the second magnetic cover plate and the bottom surface of the second carrier plate 20, and is caused by assembly tolerance. During design, optionally, the output capacitor 311 and the second magnetic cover plate 212 can be oppositely arranged up and down, that is, after assembly, the output capacitor 311 is arranged in the projection of the second magnetic cover plate 212 on the third carrier plate 30. At this time, the sum of the thickness of the output capacitor 311 and the height of H5 is less than or equal to the height H2 of the depth-controlled groove 242, so as to avoid the interference between devices when the second assembly 2 and the third assembly 3 are assembled together. In other embodiments, the output capacitor 311 can also be avoided to dispose in the area corresponding to the second magnetic cover plate 212 area, that is, after assembly, the output capacitor 311 is not arranged in the projection of the second magnetic cover plate 212 on the third carrier plate 30; and at the moment, the height of H5 needs be smaller than or equal to the height H2 of the depth-controlled groove 242, so that the interference between devices can be avoided when the second assembly 2 and the third assembly 3 are assembled together; here, H5<H1, namely, the top surface and the bottom surface of the assembled magnetic core are both concave in the top surface and the bottom surface of the connecting area 233. In the embodiment, due to the fact that the depth machining tolerance of the depth-controlled groove falls within +/−0.1 mm in a traditional PCB machining process, the depth tolerance of the depth-controlled groove and the thickness tolerance of the second carrier plate 20 are accumulated, so that the tolerance of the thickness H3 of the winding area 234 is large; and then the accumulation of the assembly tolerance between the magnetic core 210 and the carrier plate 20 is considered, the thickness of the first magnetic cover plate 211 of the magnetic core 210 and the thickness of the second magnetic cover plate 212 need to be greatly reduced, so that the performance of the magnetic core assembly is greatly reduced. The embodiment of the application provides a structure and a processing method of a second carrier plate 20, the tolerance of H3 can be greatly reduced, so that the thickness of the first magnetic cover plate 211 and the thickness of the second magnetic cover plate 212 of the magnetic core 210 are greatly increased, and the specific structure and the machining process are as follows:
Step 1, as shown in FIG. 3A, a thick copper layer 261 which is formed by flatly laying a plurality of thick copper, two double-sided copper-clad plates 262a and 262b and two PP layers 263a and 263b are prepared; in the embodiment, the PP layer is PREPRG, that is, the prepreg. The first double-sided copper-clad plate 262a, the first PP layer 263a, the thick copper layer 261, the second PP layer 263b and the second double-sided copper-clad plate 262b are sequentially stacked; the two double-sided copper-clad plates, the two PP layers and the thick copper layer are cured at a high temperature to form a substrate 260. The thickness of the two double-sided copper-clad plates 262a and the thickness of 262b can be the same or different, for example, the thickness of 262b can be greater than the thickness of 262a, so that the depth H2 of the second depth-controlled groove of the processed finished product can be greater than the depth H1 of the first depth-controlled groove. In the expanded embodiment, the two double-sided copper-clad plates 262a and 262b can also be replaced by two multilayer copper-clad plates 262a and 262b, and the two multilayer copper-clad plates 262a and 262b have preset PCB wires for connecting between the top surface bonding pad and the bottom surface pad of the signal electrical connector 236 at the position of the connecting area 233 in the substrate 260; the top surface bonding pad and the bottom surface bonding pad of the signal electrical connector 236 can be vertically aligned up and down, and can also not meet the vertical alignment position relation up and down.
Step 2, as shown in FIG. 3B, a hole is vertically drilled in the connecting area 233; then the inner wall of the hole is electroplated; then the hole is filled with a resin; finally, the top surface and the bottom surface of the hole are subjected to surface electroplating to form a top surface bonding pad and a bottom surface bonding pad; and finally, a power electric connector 235 and a signal electric connector 236 as shown in FIG. 2D are formed; the power electric connector 235 and the signal electrical connector 236 both comprise a top surface bonding pad arranged on the top surface of the substrate 260 and a bottom surface bonding pad arranged on the bottom surface of the substrate; the power electrical connector 235 is electrically connected the top surface bonding pad, the bottom surface bonding pad of the substrate 260 and the thick copper layer 261 through the via hole; and the signal electrical connector 236 is electrically connected the top surface bonding pad, the bottom surface bonding pad of the substrate 260 and the two double-sided copper-clad plates or the two multi-layer copper-clad plates through the via holes. The through hole can also be electroplated and replaced by the side wall electroplating of the printed circuit board, that is, the power electrical connector 235 is electrically connected the top surface bonding pad, the bottom surface bonding pad of the substrate 260 and the thick copper layer 261 through side wall electroplating; and the signal electrical connector 236 is electrically connected the top surface bonding pad, the bottom surface bonding pad of the substrate 260 and the two double-sided copper-clad plates or the two multi-layer copper-clad plates through side wall electroplating.
Step 3: as shown in FIG. 3C, mechanical drilling is performed on the winding area 234 to form a hole 237 penetrating through the second carrier plate 20 and used for accommodating the magnetic column of the magnetic core 210 to pass through; the hole 237 penetrates through the thick copper layer 261, so that the thick copper in the thick copper layer 261 forms a winding surrounding the magnetic column, and the magnetic column of the magnetic core 210 is surrounded by the winding in the thick copper layer 261 to form a magnetic assembly, such as an inductor.
Step 4: as shown in FIG. 3D, performing depth-controlled milling on the top surface and the bottom surface of the winding region 234 to form a first depth-controlled groove 241 and a second depth-controlled groove 242, wherein the first depth-controlled groove 241 is used for accommodating the first magnetic cover plate 211, and the second depth-controlled groove 242 is used for accommodating the second magnetic cover plate 212; the bottom surface input capacitor 112 can also be accommodated in the first depth-controlled groove 241; and the output capacitor 311 can also be accommodated in the second depth-controlled groove 242. The depth of the depth-controlled milling groove can be controlled to retain residual PP with a certain thickness on the thick copper layer 261.
Step 5, as shown in FIG. 3E, the residual PP reserved in the step 4 is removed through a laser etching process; because the energy of the laser is not enough to reduce the thick copper, the thick copper layer 261 in the step 1 is finally reserved in the vertical direction of the winding area 234.

Optionally, an insulating layer is formed on the surface of the exposed thick copper layer 261 in the step 5 in a spraying mode, such as green oil; on one hand, the thick copper layer 261 can be insulated from an external device such as a magnetic core 210, a bottom surface input capacitor 112 or an output capacitor 311; and on the other hand, the effect of preventing moisture can be achieved, so that the reliability of the module is further enhanced.

Through the second assembly 2 formed by the machining process flow, the tolerance of the thickness H3 of the remaining winding area 234 in FIG. 3E is equal to the tolerance of the thick copper layer 261, so that the tolerance of the thickness H3 of the winding area 234 is greatly reduced; the depth tolerance of the first depth-controlled groove 241 and the tolerance of the depth of the second depth-controlled groove 242 are eliminated; and the thickness of the first magnetic cover plate 211 and the thickness of the second magnetic cover plate 212 can be greatly increased. In addition, a winding formed by the thick copper layer 261 enables the space utilization rate of the winding position to reach 100%. In conclusion, the characteristics and the processing flow of the second carrier plate 20 provided by the embodiment enable the space utilization rate of the magnetic core position and the winding position to be maximized, so that the performance of the magnetic assembly in the second assembly 2 can be greatly improved.

Preferably, a bonding layer is also included between the insulation layer on the surface of the thick copper layer 261 and the magnetic core, which serves to fix the magnetic core and the thick copper layer. This bonding layer and the insulation layer are both made of organic materials, which can provide better protection for the bonding layer and prevent a reduction in bonding strength. Compared to the thick copper layer without the insulation layer, the bonding strength between the magnetic core and the thick copper layer with the insulation layer is greater than the bonding strength between the magnetic core and the thick copper layer without the insulation layer. The thick copper layer here can be made of pure copper material, or it can have a surface coating of nickel-gold, nickel-tin, or nickel, with no specific limitation on the surface treatment of the thick copper layer. The bonding layer and/or insulation layer can cover part or all of the thick copper layer, and the application of such magnetic components is not limited to the power modules disclosed in this invention. They can also be applied to other types of power modules or electronic devices.

The switch tube disclosed by the application can be used for realizing the functions of the switch disclosed by the application, such as a Si MOSFET, SiC MOSFET, GaN MOSFET or IGBT MOSFET.

The power conversion device according to the embodiment can be an independent module or a part of the electronic device, and can meet the technical features and advantages disclosed by the application.

The “equal” or “same” or “equal to” disclosed by the application needs to consider the parameter distribution of engineering, and the error distribution is within +/−30%; and the included angle between the two line segments or the two straight lines is less than or equal to 45 degrees; the included angle between the two line segments or the two straight lines is within the range of [60, 120]; and the definition of the phase error phase also needs to consider the parameter distribution of the engineering, and the error distribution of the phase error degree is within +/−30%.

The embodiments in the specification are described in a progressive manner, each embodiment focuses on the difference from other embodiments, and the same similar parts between the embodiments can be referred to each other.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. A manufacturing method of a carrier plate comprises the following steps:
step 1, preparing thick copper, a first double-sided copper-clad plate, a second double-sided copper-clad plate, a first PP layer and a second PP layer, wherein the first double-sided copper-clad plate is arranged on a top surface of the thick copper through a first PP layer, the second double-sided copper-clad plate is arranged on a bottom surface of the thick copper through a second PP layer, and the double-sided copper-clad plates, the PP layers and the thick copper are cured at high temperature to form a substrate; the substrate comprises a connecting area and a winding area;
step 2, a hole is vertically drilled in the connecting area, and after the inner wall of the hole is electroplated and the hole is filled with a resin, a top surface and a bottom surface of the hole are subjected to surface electroplating to form a connector; the connector is electrically connected with the thick copper;
step 3, performing mechanical drilling on the winding area to form a hole penetrating through the substrate; and
step 4, performing depth-controlled milling on the top surface and the bottom surface of the winding area to form a first depth-controlled groove and a second depth-controlled groove.

2. The manufacturing method of claim 1, wherein a sum of a thicknesses of the first double-sided copper-clad plate and the first PP layer is equal to a sum of a thicknesses of the second double-sided copper-clad plate and the second PP layer; and a height of the first depth-controlled groove is equal to a height of the second depth-controlled groove.

3. The manufacturing method of claim 1, wherein the connector is electrically connected with a wiring layer in the substrate, and the connector comprises a top surface bonding pad arranged on the top surface of the substrate and a bottom surface bonding pad arranged on the bottom surface of the substrate.

4. The manufacturing method of claim 1, wherein part of PP layers are reserved at bottoms of the first depth-controlled groove and the second depth-controlled groove, and the PP layers is removed through a laser etching process.

5. The manufacturing method of claim 4, wherein an insulating layer is formed on the exposed surface of the thick copper in a spraying mode to form a carrier plate.

6. A power supply module comprises a first assembly, a second assembly and a third assembly; and the first assembly, the second assembly and the third assembly are sequentially stacked; and the second assembly comprises a carrier plate and a magnetic core; and the carrier plate comprises a top surface and a bottom surface which are opposite to each other, a hole, a connector, a first depth-controlled groove, a second depth-controlled groove, a winding area and a connecting area; the first depth-controlled groove is concaved from the top surface of the carrier plate, and the second depth-controlled groove is concaved from the bottom surface of the carrier plate; the winding area is a part of a second carrier plate between the first depth-controlled groove and the second depth-controlled groove; the hole is formed in the winding area, and the hole penetrates through the top surface and the bottom surface of the carrier plate; the connector is provided with the connecting area; the power supply module further comprises a winding, and the winding is arranged in a winding area of the carrier plate;
the magnetic core comprises a magnetic column, a first magnetic cover plate and a second magnetic cover plate, the magnetic column penetrates through the hole, the first magnetic cover plate and the second magnetic cover plate are accommodated in the first depth-controlled groove and the second depth-controlled groove respectively, and the first magnetic cover plate and the second magnetic cover plate are buckled with the magnetic column;
the first assembly and the third assembly are arranged on a top surface and a bottom surface of the second assembly respectively, and the first assembly and the third assembly are electrically connected through the connector.

7. The power supply module of claim 6, wherein a thickness of the first magnetic cover plate is smaller than or equal to a height of the first depth-controlled groove, and the thickness of the second magnetic cover plate is smaller than or equal to the height of the second depth-controlled groove.

8. The power module of claim 6, wherein the carrier plate is a second carrier plate; the first assembly comprises a first carrier plate, a switch device and an input capacitor; the first carrier plate comprises a top surface and a bottom surface which are opposite; the bottom surface of the first carrier plate is arranged adjacent to a top surface of the second carrier plate; the switch device is arranged on the top surface of the first carrier plate; and the input capacitor is arranged on the bottom surface of the first carrier plate.

9. The power supply module according to claim 8, the input capacitor is accommodated in the first depth-controlled groove, and a sum of the thickness of the input capacitor and the thickness of the first magnetic cover plate is smaller than or equal to a height of the first depth-controlled groove.

10. The power supply module of claim 8, wherein the third assembly comprises a third carrier plate, an output capacitor and a welding ball; the third carrier plate comprises a top surface and a bottom surface opposite to each other, and the top surface of the third carrier plate is arranged adjacent to a bottom surface of the second carrier plate; and the output capacitor is arranged on the top surface of the third carrier plate, and the solder ball is arranged on the bottom surface of the third carrier plate.

11. The power supply module of claim 10, wherein the output capacitor is accommodated in the second depth-controlled groove, and a sum of the thickness of the output capacitor and the thickness of the second magnetic cover plate is smaller than or equal to the height of the second depth-controlled groove.

12. The power supply module of claim 6, wherein the connector comprises a via hole, a top surface bonding pad and a bottom surface bonding pad; and the via hole is electrically connected with the top surface bonding pad and the bottom surface bonding pad.

13. The power supply module of claim 6, wherein the connector comprises side wall electroplating, a top surface bonding pad and a bottom surface bonding pad, and the side wall electroplating is electrically connected to the top surface bonding pad and the bottom surface bonding pad.

14. The power supply module of claim 12, wherein the connector comprises a power electrical connector and a signal electrical connector; and the carrier plate further comprises a thick copper layer and a copper-clad layer, and the signal electrical connector is electrically connected with the thick copper layer and the copper-clad layer.

15. The power supply module of claim 6, the connection area surrounds the winding area.

16. The power supply module of claim 6, wherein the winding is an internal wiring of the carrier plate or a copper sheet embedded in the carrier plate.

17. The power supply module of claim 6, further comprises a bonding layer and an insulation layer, the bonding layer and/or the insulation layer is capable of covering part or whole of the winding and the bonding layer is disposed between the magnetic core and the insulation layer.

18. A method for assembling the power supply module of claim 10 comprises the following steps:
step 1, buckling the magnetic core and the second carrier plate to form a second assembly;
step 2, welding an output capacitor and the second assembly formed in the step 1 on the top surface of the third carrier plate to form a first assembly;
step 3, ball-implanting a ball on the bottom surface of the third carrier plate to form a second combination body;
step 4, welding a switch device on the top surface of the first carrier plate;
step 5, welding an input capacitor and the second combination body formed in the step 3 on the bottom surface of the first carrier plate to form the power supply module, the step 4 is completed in any step before the step 5.

19. A method for assembling the power supply module of claim 10 comprises the following steps:
step 1, buckling the magnetic core and the second carrier plate to form a second assembly;
step 2, ball-implanting a solder ball on the bottom surface of the third carrier plate;
step 3, welding an output capacitor and the second assembly formed in the step 1 on the top surface of the third carrier plate to form a first combination body;
step 4, welding a switch device on the top surface of the first carrier plate;
step 5, welding an input capacitor and the first combination body formed in the step 3 on the bottom surface of the first carrier plate to form the power supply module, the step 2 is completed in any step before the step 3, and the step 4 is completed in any step before the step 5.

20. A method for assembling the power supply module of claim 10 comprises the following steps:
step 1, buckling the magnetic core and the second carrier plate to form a second assembly;
step 2, ball-implanting a solder ball on the bottom surface of the third carrier plate;
step 3, welding an input capacitor and the second assembly formed in the step 1 on the bottom surface of the third carrier plate to form a first combination body;
step 4, welding a switch device on the top surface of the first carrier plate;
step 5, welding an output capacitor and the first combination body formed in the step 3 on the top surface of the third carrier plate to form the power supply module, the step 2 is completed in any step before the step 3, and the step 4 is completed in any step before the step 5.

21. A method for assembling the power supply module of claim 10 comprises the following steps:
step 1, buckling the magnetic core and the second carrier plate to form a second assembly;
step 2, welding an output capacitor and a second assembly formed in the step 1 on the top surface of the third carrier plate to form a first combination body;
step 3, welding a switch device and a top surface input capacitor on the top surface of the first carrier plate;
step 4, arranging a bottom surface input capacitor and the first combination body formed in the step 2 on the bottom surface of the first carrier plate, arranging a welding ball on the bottom surface of the third carrier plate, and carrying out reflow soldering to form a power supply module, the step 3 is completed in any step before the step 4.

22. A magnetic assembly comprises a carrier plate, a magnetic core and a winding; the winding is an internal wiring of the carrier plate or a metal sheet embedded in the carrier plate; the magnetic core comprises a magnetic column, a first magnetic cover plate and a second magnetic cover plate, the magnetic column is disposed between the first magnetic cover plate and the second magnetic cover plate; the carrier plate comprises a top surface and a bottom surface which are opposite to each other, and a hole penetrates through the top surface and the bottom surface of the carrier plate; the magnetic column penetrates through the hole, and the first magnetic cover plate and the second magnetic cover plate are buckled the carrier plate with the magnetic column;
the magnetic assembly further comprises a bonding layer and an insulation layer, the bonding layer and/or the insulation layer is capable of covering part or whole of the winding and the bonding layer is disposed between the magnetic core and the insulation layer.

23. The magnetic assembly of claim 22, the carrier plate comprises a first depth-controlled groove, a second depth-controlled groove, a winding area and a connecting area; the first depth-controlled groove is concaved from the top surface of the carrier plate, and the second depth-controlled groove is concaved from the bottom surface of the carrier plate; the winding area is part of a carrier plate between a first depth-controlled groove and a second depth-controlled groove; the hole is arranged in the winding area; the first magnetic cover plate and the second magnetic cover plate are accommodated in the first depth-controlled groove and the second depth-controlled groove respectively.

24. The magnetic assembly of claim 23, the connection area surrounds the winding area; the magnetic assembly further comprises a connector, wherein the connector comprises a via hole, a top surface bonding pad and a bottom surface bonding pad; and the via hole is electrically connected with the top surface bonding pad and the bottom surface bonding pad.

25. The magnetic assembly of claim 24, wherein the connector comprises a power electrical connector and a signal electrical connector; and the carrier plate further comprises a thick copper layer and a copper-clad layer, and the signal electrical connector is electrically connected with the thick copper layer and the copper-clad layer.
